(19) United States
(12) Patent Application Publication
(10) Pub. No.: US 2026/0114156 A1
(43) Pub. Date: Apr. 23, 2026

(54) DISPLAY DEVICE, METHOD OF MANUFACTURING THE SAME AND ELECTRONIC DEVICE INCLUDING THE SAME

(71) Applicant: Samsung Display Co., LTD., Yongin-si (KR)

(72) Inventors: Chang Moo LEE, Yongin-si (KR); Ji Hyun KO, Yongin-si (KR); Dong Hwan KIM, Yongin-si (KR); Jung Hoon SHIN, Yongin-si (KR); Jun Woo YOU, Yongin-si (KR)

(73) Assignee: Samsung Display Co., LTD., Yongin-si (KR)

(21) Appl. No.: 19/278,031

(22) Filed: Jul. 23, 2025

(30) Foreign Application Priority Data
Oct. 23, 2024 (KR) 10-2024-0145798

(51) Int. Cl. H10K 59/80

(52) U.S. Cl. CPC H10K 59/873

(57) ABSTRACT

A display device includes a display panel including a pixel structure, a polarizing plate disposed on the display panel, and a curl-suppression layer disposed on or under the display panel. The polarizing plate includes a polarizer that has a stretching axis in a first stretching direction parallel to an upper surface of the display panel. The curl-suppression layer is stretched in a second stretching direction crossing the first stretching direction and includes an ultra-high molecular weight polyethylene (UHMWPE).

### CROSS-REFERENCE TO RELATED APPLICATION(S)

This application claims priority to and benefits from Korean Patent Application No. 10-2024-0145798 under 35 U.S.C. § 119, filed on Oct. 23, 2024 in the Korean Intellectual Property Office (KIPO), the entire contents of which are incorporated herein by reference.

### BACKGROUND

### 1. Technical Field

Embodiments of the disclosure relate to a display device including a display panel and a functional layer, a method of manufacturing the same, and an electronic device including the same.

### 2. Description of the Related Art

A display device such as an organic light-emitting display device or a liquid crystal display device may include a polarizing plate to prevent reflection of an external light and to increase light efficiency. The polarizing plate may include a polarizer containing polyvinyl alcohol (PVA). The polarizer may have polarization properties by dyeing and stretching processes.

With recent developments of display devices having flexible, foldable and/or bendable properties, a thickness of a substrate or a panel included in the display device is decreasing. Accordingly, overall mechanical properties of the display device may be readily transformed or deteriorated even by the polarizing plate.

### SUMMARY

Embodiments provide a display device having improved mechanical property and reliability.

Embodiments also provide a method of manufacturing a display device having improved mechanical property and reliability.

Embodiments also provide an electronic device including a display device that has improved mechanical property and reliability.

A display device may include a display panel including a pixel structure, a polarizing plate disposed on the display panel, and a curl-suppression layer disposed on or under the display panel. The polarizing plate may include a polarizer that has a stretching axis in a first stretching direction parallel to an upper surface of the display panel. The curl-suppression layer may be stretched in a second stretching direction crossing the first stretching direction and may include an ultra-high molecular weight polyethylene (UHMWPE).

In some embodiments, a tensile modulus of the curl-suppression layer may be in a range from about 70 GPa to about 130 GPa.

In some embodiments, a thickness of the curl-suppression layer may be greater than a thickness of the polarizer.

In some embodiments, a thickness of the polarizer may be in a range from about 10 μm to about 15 μm, and a thickness of the curl-suppression layer may be in a range from about 12 μm to about 400 μm.

In some embodiments, the first stretching direction may form a first crossing angle with a longitudinal direction of the display panel, and the second stretching direction may be parallel to the upper surface of the display panel and may form a second crossing angle with the first stretching direction.

In some embodiments, the first crossing angle may be in a range from about 20° to about 70°.

In some embodiments, the second crossing angle may be in a range from about 60° to about 90°.

In some embodiments, the polarizing plate and the curl-suppression layer may be sequentially stacked on each other from the upper surface of the display panel.

In some embodiments, the curl-suppression layer may be disposed between the display panel and the polarizing plate.

In some embodiments, the curl-suppression layer may serve as an outermost layer of the display device.

In some embodiments, the display device may further include a cover panel disposed under the display panel. The cover panel and the display panel may be sequentially stacked on each other from the curl-suppression layer.

In some embodiments, the display device may further include a cover panel under the display panel. The curl-suppression layer may be disposed between the display panel and the cover panel.

In some embodiments, the curl-suppression layer may be directly attached to an upper surface or a lower surface of the polarizer.

In some embodiments, the polarizing plate may further include a protective film attached to a surface to which the curl-suppression layer may not be attached to the upper surface or the lower surface of the polarizer.

In some embodiments, the display device may further include a quarter-wavelength plate disposed between the polarizer and the display panel. The curl-suppression layer may be disposed between the quarter-wavelength plate and the polarizer.

A display device may include a display panel including a pixel structure, a polarizing plate disposed on the display panel, and a curl-suppression layer disposed on or under the display panel. The polarizing plate may include a polarizer that has a stretching axis in a first stretching direction parallel to an upper surface of the display panel. The curl-suppression layer may be stretched in a second stretching direction crossing the first stretching direction and may have a tensile modulus in a range of about 70 GPa to about 130 GPa.

In some embodiments, the curl-suppression layer may include an ultra-high molecular weight polyethylene (UHMWPE).

An electronic device may include a display device, a memory, and a processor that executes data included in the memory to control an operation of the display device. The display device may include a display panel including a pixel structure, a polarizing plate disposed on the display panel, and a curl-suppression layer disposed on or under the display panel. The polarizing plate may include a polarizer that has a stretching axis in a first stretching direction parallel to an upper surface of the display panel. The curl-suppression layer may be stretched in a second stretching direction crossing the first stretching direction and may include an ultra-high molecular weight polyethylene (UHMWPE).

In some embodiments, a tensile modulus of the curl-suppression layer may be in a range from about 70 GPa to about 130 GPa.

In some embodiments, the electronic device may include virtual or augmented reality glasses, a smartphone, a tablet PC, a laptop, a TV, a desk monitor, smart glasses, a head mounted display, a smart watches, or a vehicle display.

According to the above-described embodiments, a curl-suppression layer having a stretching direction crossing a stretching direction of a polarizing plate may be included in a display device. The curl-suppression layer may be used to buffer or suppress a curl of the display device caused by a stretching axis or an absorption axis of the polarizing plate.

According to embodiments of the disclosure, the curl-suppressing layer may include an ultra-high molecular weight polyethylene (UHMWPE), and the curl of the display device may be prevented by high modulus properties of UHMWPE.

### BRIEF DESCRIPTION OF THE DRAWINGS

The accompanying drawings, which are included to provide a further understanding of the invention and are incorporated in and constitute a part of this specification, illustrate embodiments of the disclosure, and together with the description serve to explain the invention.

FIG. 1 is a schematic exploded perspective view illustrating a display device according to embodiments.

FIGS. 2 and 3 are schematic cross-sectional views illustrating display devices according to embodiments.

FIGS. 4 and 5 are partially enlarged schematic cross-sectional views illustrating display devices according to embodiments.

FIG. 6 is a schematic exploded perspective view showing alignment of stretching directions of a curl-suppression layer and a polarizer.

FIGS. 7A, 7B, and 7C are schematic perspective views showing a stretching process of a curl-suppression layer according to embodiments.

FIGS. 8 to 12 are schematic cross-sectional views illustrating a combination of a polarizing plate and a curl-suppression layer according to embodiments.

FIGS. 13 to 15 are schematic cross-sectional views illustrating display devices according to embodiments.

FIGS. 16 to 19 are schematic cross-sectional views illustrating a method of manufacturing a display device according to embodiments.

FIGS. 20 and 21 are schematic cross-sectional views illustrating a method of manufacturing a display device according to some embodiments.

FIG. 22 is a schematic block diagram of an electronic device in accordance with an embodiment.

FIG. 23 is a schematic diagram of an electronic device in accordance with various embodiments.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or redisposed without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure. For example, the terms “first adhesive layer 50,” “second adhesive layer 60,” and “third point adhesive layer 70” recited herein are used to distinguish adhesive layers for attaching a polarizing plate 200, a curl-suppression layer 300 and a window structure WS, respectively.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the disclosure. Further, the blocks, parts, and/or modules of some embodiments may be physically combined into more complex blocks, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly defined so herein.

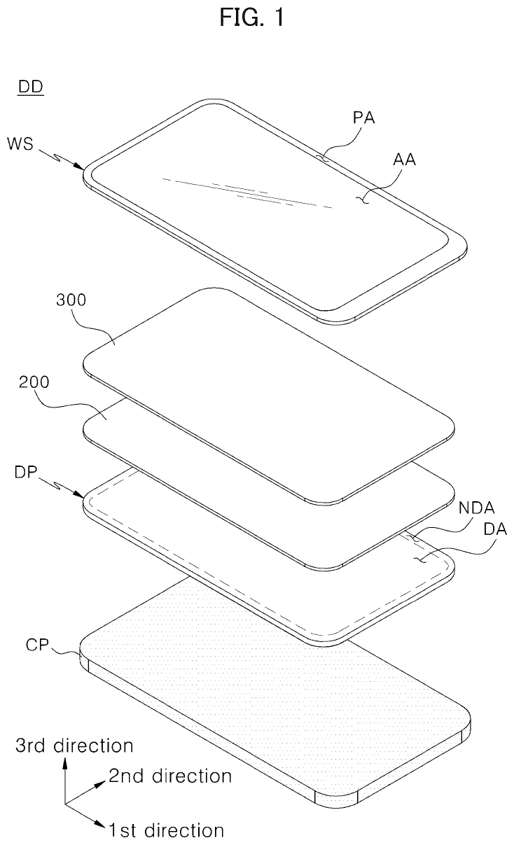

FIG. 1 is a schematic exploded perspective view illustrating a display device according to embodiments.

Referring to FIG. 1, a display device DD may include a window structure WS, a display panel DP, and a cover panel CP.

The display device DD may include a liquid crystal display (LCD) device, an organic light emitting diode (OLED) display device, a quantum dot light emitting diode (QLED) display device, a quantum dot (QD)-organic light emitting diode (OLED) display device, or the like. According to embodiments, the display device DD may be implemented as an electronic device in the form of a mobile phone.

In FIG. 1, a first direction and a second direction may refer to two directions being parallel to a display surface of the window structure WS and/or the display panel DP and crossing each other. For example, the first direction and the second direction may be orthogonal to each other.

For example, the first direction may correspond to a length direction of the display device DD or the display panel DP, and the second direction may correspond to a width direction of the display device DD or the display panel DP.

The third direction may be perpendicular to the first direction and the second direction. The third direction may correspond to a thickness direction of the display device DD or the display panel DP.

In the accompanying drawings, the above definitions of the directions may be equally applied.

The cover panel CP, the display panel DP and the window structure WS may be sequentially stacked on each other in the third direction.

The window structure WS may provide an external display surface of the display device DD that is recognized by a user, and may include a transparent film. For example, the window structure WS may include glass (e.g., ultra-thin glass (UTG)), a hard coating film, a plastic film, or the like.

An outer surface of the window structure WS may include an active area AA and a peripheral area PA. The active area AA may substantially display an image of the display device DD, and may provide a surface to which a user's touch/command is input. The peripheral area PA may substantially correspond to a bezel area of the display device DD.

The display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

The cover panel CP may serve as a rear panel or a rear housing of the display device DD. The cover panel CP may include a plate (e.g., an SUS plate) that supports the display panel DP, the circuit board (PCB), or the like. The cover panel CP may include an elastic body for absorbing shock of the display device DD.

According to embodiments of the disclosure, the polarizing plate 200 and the curl-suppression layer 300 may be disposed on the display panel DP.

In some embodiments, the window structure WS may be omitted. The display device DD may serve as an ultra-thin (UT) display.

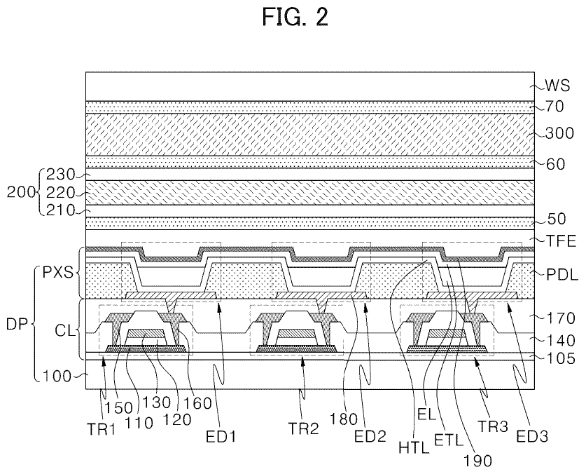

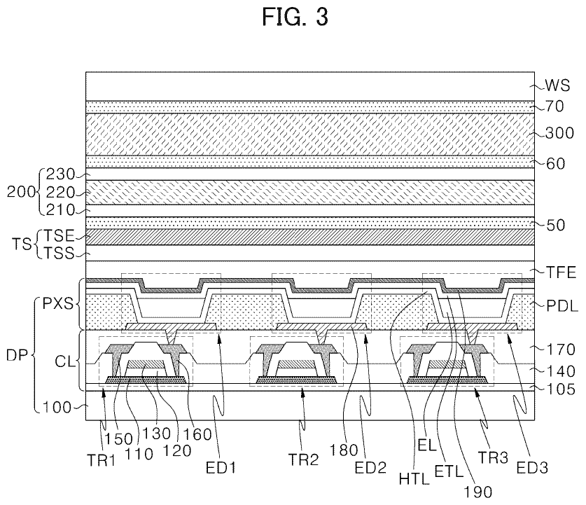

FIGS. 2 and 3 are schematic cross-sectional views illustrating display devices according to embodiments. For convenience of descriptions, illustration of the cover panel CP is omitted in FIGS. 2 and 3.

Referring to FIG. 2, the display device may include the display panel DP, the polarizing plate 200, and the curl-suppression layer 300 stacked on each other on the display panel DP. The display panel DP may include a base substrate 100, a circuit layer CL stacked on each other on the base substrate 100, and a pixel structure PXS disposed on the circuit layer CL.

The base substrate 100 may serve as a supporting substrate or a back-plane substrate of an image display device. A glass substrate or a plastic substrate may be used as the base substrate 100.

In some embodiments, the base substrate 100 may include a polymer material having transparent and flexible properties. The base substrate 100 may be applied in a transparent flexible display device. For example, the base substrate 100 may include a polymer material such as polyimide, polysiloxane, an epoxy resin, an acrylic resin, polyester, or a combination thereof. In an embodiment, the base substrate 100 may include polyimide.

The circuit layer CL including transistors TR1, TR2 and TR3 may be formed on the base substrate 100. The circuit layer may include wiring layers and insulating layers that form a thin film transistor array (TFT-Array).

The circuit layer CL may further include a buffer layer 105 on a top (or upper) surface of the base substrate 100. The buffer layer 105 may block penetration of moisture through the base substrate 100, and may also block diffusion of impurities between the base substrate 100 and structures formed thereon.

The buffer layer 105 may include an inorganic insulating material such as silicon oxide, silicon nitride or silicon oxynitride. The buffer layer 105 may include one of the aforementioned materials, or a combination thereof. In some embodiments, the buffer layer 105 may have a stacked structure including a silicon oxide layer and a silicon nitride layer.

The buffer layer 105 may be formed by a deposition process such as a chemical vapor deposition (CVD) process, a sputtering process, an atomic layer deposition (ALD) process, or the like, to include the inorganic insulating material.

The transistors TR1, TR2 and TR3 may be disposed on the buffer layer 105. A first transistor TR1, a second transistor TR2 and a third transistor TR3 may be electrically connected to a first light-emitting device ED1, a second light-emitting device ED2 and a third light-emitting device ED3, respectively.

The transistors TR1, TR2 and TR3 may each include an active layer 110, a gate insulation layer 120, a gate electrode 130 and connection electrodes 150 and 160.

The active layer 110 may be disposed on the buffer layer 105, and may be regularly and repeatedly patterned for each pixel by, e.g., a photo-lithography process. The active layer 110 may include a silicon compound such as amorphous silicon or polysilicon. A p-type dopant or an n-type dopant may be doped in a region of the active layer 110, and the active layer 110 may include a source region, a drain region, and a channel region.

The active layer 110 may include an oxide semiconductor, such as indium gallium zinc oxide (IGZO), zinc tin oxide (ZTO), or ITZO.

The gate insulation layer 120 may be formed on the active layer 110, and the gate electrode 130 may be stacked on each other on the gate insulation layer 120. As illustrated in FIG. 5, the gate insulation layer 120 may be patterned to partially cover each active layer 110. The gate insulation layer 120 may extend continuously over multiple pixels or light-emitting regions, and may be provided as a common layer for the first, second and third transistors TR1, TR2 and TR3.

The gate electrode 130 may overlap the channel region of the active layer 110 in a vertical direction.

The gate insulation layer 120 may be formed by the above-described deposition process to include an inorganic insulating material such as silicon oxide, silicon nitride, silicon oxynitride, or the like. In some embodiments, the gate insulation layer 120 having a patterned shape may be formed as illustrated in FIG. 2 by a photo-lithography process in which the gate electrode 130 may be substantially used as an etching mask.

In some embodiments, the gate electrode 130 and the gate insulation layer 120 may be used as ion implantation masks to form the source region and the drain region in the active layer 110.

An insulating interlayer 140 may be formed on the active layer 110 to cover the gate electrode 130 and the gate insulation layer 120. The connection electrodes 150 and 160 which may be in contact with or electrically connected to the active layer 110 may be formed on the insulating interlayer 140.

The insulating interlayer 140 may be formed by the above-described deposition process to include an inorganic insulating material such as silicon oxide, silicon nitride, silicon oxynitride, or the like. The insulating interlayer 140 may be formed in a single-layered structure or a multi-layered structure including different materials.

In some embodiments, in case that the active layer 110 includes an oxide semiconductor, hydrogen (H) included in the insulating interlayer 140 may be diffused or transferred to the active layer 110 through a heat-treatment process when forming the insulating interlayer 140. Accordingly, a carrier concentration may be increased by hydrogen so that the source region and the drain region having an increased conductivity may be formed at edge portions of the active layer 110.

The connection electrodes 150 and 160 may penetrate the insulating interlayer 140, and may be connected to the active layer 110. In case that the gate insulation layer 120 is continuously formed commonly in multiple the pixel regions, the connection electrodes 150 and 160 may also penetrate the gate insulation layer 120.

The connection electrodes 150 and 160 may include a source electrode 150 connected to or in contact with the source region of the active layer 110 and a drain electrode 160 connected to or in contact with the drain region of the active layer 110.

Contact holes may be formed by partially etching the insulating interlayer 140. For example, the contact holes exposing the source region and the drain region may be formed. A metal layer sufficiently filling the contact holes may be formed on the insulating interlayer 140, and then the metal layer may be partially etched to form the source electrode 150 and the drain electrode 160.

The gate electrode 130 and the connection electrodes 150 and 160 may include a metal such as Ag, Mg, Al, W, Cu, Ni, Cr, Mo, Ti, Pt, Ta, Nd, Sc, or the like, an alloy thereof, or a nitride thereof. The gate electrode 130 and the connection electrodes 150 and 160 may be formed by the above-mentioned deposition process and the photo-lithography process.

A planarization layer 170 covering (or overlapping) the connection electrodes 150 and 160 may be formed on the insulating interlayer 140. The planarization layer 170 may accommodate a via structure electrically connecting the pixel electrode 180 and the drain electrode 160.

In some embodiments, the planarization layer 170 may include an organic material such as polyimide, an epoxy resin, an acrylic resin, polyester, a siloxane resin, a benzocyclobutene (BCB), the like, or a combination thereof. The planarization layer 170 may be formed by the above-described deposition process or a spin coating process.

A pixel electrode 180 may be formed in each pixel to be electrically connected to the transistors TR1, TR2 and TR3. The pixel electrode 180 may be formed on the planarization layer 170 to be electrically connected to the drain electrode 160.

For example, the planarization layer 170 may be partially etched to form a via hole exposing a top surface of the drain electrode 160. A conductive layer including a metal or a transparent conductive oxide and sufficiently filling the via hole may be formed on the top surface of the planarization layer 170, and then the conductive layer may be etched to form the pixel electrode 180.

The pixel electrode 180 may serve as an anode and may include a high work function conductive material that promotes hole injection. The pixel electrode 180 may serve as a transmissive electrode. The pixel electrode 180 may include a transparent conductive oxide such as indium tin oxide (ITO), indium zinc oxide (IZO), zinc oxide (ZnO), indium tin oxide (ITZO), or the like.

The pixel electrode 180 may serve as a translucent electrode or a reflective electrode. The pixel electrode 180 may include a metal selected from Ag, Mg, Cu, Al, Pt, Pd, Au, Ni, Nd, Ir, Cr, Li, Ca, LiF, Mo, Ti, W, In, Sn, and Zn, or an alloy of two or more therefrom.

The pixel electrode 180 may have a single-layered structure or a multi-layered structure. For example, the pixel electrode 180 may have a triple-layered structure of ITO/Ag/ITO.

A pixel structure PXS including a pixel defining layer PDL and a light-emitting portion may be disposed on the circuit layer CL.

The pixel defining layer PDL may be formed on the planarization layer 170 to expose a top surface of the pixel electrode 180. A light-emitting region may be defined by a sidewall of the pixel defining layer PDL. A red light-emitting region, a green light-emitting region, and a blue light-emitting region may be separated and defined by the pixel defining layer PDL, and the first light-emitting device ED1, the second light-emitting device ED2, and the third light-emitting device ED3 may correspond to a blue light-emitting device, a green light-emitting device, and the red light-emitting device, respectively.

In some embodiments, all of the light-emitting devices ED1, ED2 and ED3 may be a white light-emitting device or a blue light-emitting device.

The light-emitting portion may be disposed in each light-emitting region formed by the pixel defining layer PDL. According to embodiments, the light-emitting portion may include an emission layer EL including an organic light-emitting material. For example, the emission layer EL may include a fluorescent host and/or a phosphorescent host, and may further include a fluorescent dopant, a phosphorescent dopant and/or a thermally activated delayed fluorescent (TADF) dopant.

For example, the light-emitting portion may be formed by a process such as a vacuum deposition, a spin coating, an inkjet printing, a laser printing, a casting, a laser thermal transfer, or the like.

A counter electrode 190 may be disposed on a top surface of the pixel defining layer PDL and the light-emitting portions. The counter electrode 190 may be a common electrode that may be continuously and commonly provided in multiple the light-emitting regions or the pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in combination of two or more therefrom.

The counter electrode 190 may be formed as a transmissive electrode, a translucent electrode, or a reflective electrode. The counter electrode 190 may have a single-layered structure or a multi-layered structure.

The light-emitting portion may further include a hole transport layer HTL and an electron transport layer ETL. According to embodiments, the hole transport layer HTL, the emission layer EL, the electron transport layer ETL and the counter electrode 190 may be sequentially stacked on each other from the top surface of the pixel electrode 180.

For example, the hole transport layer HTL may include an hole transport material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer (ETL) may include an electron transport materials such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen)-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further disposed between the pixel electrode 180 and the hole transport layer HTL. An electron injection layer may be further disposed between the counter electrode 190 and the electron transport layer ETL.

In some embodiments, the layers included in the above-described light-emitting portion may be patterned in the light-emitting region defined by the pixel defining layer PDL similarly to the emission layer EL illustrated in FIG. 2. Accordingly, the light-emitting portions may be separated from each other in the form of an island in multiple the pixels.

In some embodiments, the layers included in the above-described light-emitting portion may continuously and commonly extend throughout multiple the pixel regions and the top surface of the pixel defining layer PDL.

In some embodiments, an encapsulation layer TFE covering (or overlapping) the pixel structure PXS may be disposed on the display panel DP. In an embodiment, the encapsulation layer TFE may be included as a component of the display panel DP.

The encapsulation layer TFE may be disposed on the pixel defining layer PDL and the light-emitting devices ED1, ED2 and ED3 to protect the light-emitting devices ED1, ED2 and ED3 from moisture or oxygen.

The encapsulation layer TFE may include an inorganic layer including silicon nitride (SiNₓ), silicon oxide (SiOₓ), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or any combination thereof; or a combination of the inorganic and organic layers.

The encapsulation layer TFE may be formed in a single-layered or a multi-layered structure. In some embodiments, the encapsulation layer TFE may have a sequential stacked structure of a first inorganic layer, an organic layer and a second inorganic layer.

In some embodiments, the display panel DP may further include a color control portion disposed on the pixel structure PXS. The color control portion may include a color filter corresponding to each of the light-emitting devices ED1, ED2 and ED3 or each pixel.

The color filter may selectively transmit a light of a specific wavelength band, and may substantially absorb a remaining light. Accordingly, color purity of the display device DD may be increased, and reflection of an external light may be decreased.

The color filter may include a first color filter that transmits a blue light having, e.g., a central wavelength ranging from about 420 nm to about 480 nm, a second color filter that transmits a green light having, e.g., a central wavelength ranging from about 500 nm to about 580 nm, and a third color filter that transmits a red light having, e.g., a central wavelength ranging from about 600 nm to about 670 nm.

The first to third color filters may correspond to the first to third light emitting devices ED1, ED2 and ED3, respectively.

The color control portion may include a color conversion portion including, e.g., quantum dots between the color filter and the light-emitting device. The display device DD may be provided as a QD-OLED device. For example, a color of emitted light may be adjusted according to a particle size of the quantum dots. The quantum dots may be classified into blue quantum dots, red quantum dots and green quantum dots.

The color conversion portion may include a first color conversion layer, a second color conversion layer and a third color conversion layer corresponding to and overlap the first light-emitting device ED1, the second light-emitting device ED2 and the third light-emitting device ED3, respectively, in the third direction.

According to embodiments, a blue light having a central wavelength in a range of, e.g., 420 nm to 480 nm may be generated from the light-emitting portion. The first color conversion layer corresponding to the first light-emitting device ED1 may transmit the blue light. The color conversion layer may not include the quantum dots, and may include a scattering material. The scattering material may include TiO₂, ZnO, Al₂O₃, SiO₂, hollow silica, or the like. They may be used alone or in a combination of two or more therefrom.

The second color conversion layer corresponding to the second light-emitting device ED2 may convert the blue light into a green light having a central wavelength in a range of, e.g., about 500 nm to about 580 nm.

The third color conversion layer corresponding to the third light-emitting device ED3 may convert the blue light into a red light having a central wavelength in a range of, e.g., about 600 nm to about 670 nm.

In some embodiments, the first to third light-emitting devices ED1, ED and ED3 may be light-emitting devices having a tandem structure that may emit the same white light or the blue light. The first to third light-emitting devices ED1, ED2 and ED3 may be stacked on each other in the third direction for each pixel or the light-emitting region defined by the pixel defining layer PDL with a charge generation layer disposed therebetween.

The polarizing plate 200 and the curl-suppression layer 300 may be disposed on the display panel DP.

The polarizing plate 200 may include a polarizer 220. A protective film may be attached to surfaces of the polarizer 220 to provide the polarizing plate 200 in the form of a film.

The polarizer 220 may include an iodine-dyed polyvinyl alcohol (PVA) film. The polarizer 220 may be stretched in a specific uniaxial direction to provide polarization properties as iodine molecules are oriented.

The protective film may include a first protective film 210 attached to a bottom (or lower) surface of the polarizer 220 and a second protective film 230 attached to a top (or upper) surface of the polarizer 220.

The protective films 210 and 230 may include a resin film having improved transparency, mechanical strength, thermal stability, water-shielding properties, isotropic properties, etc. For example, the protective films 210 and 230 may include an acrylic resin film such as polymethyl(meth)acrylate and polyethyl(meth)acrylate; a polyester resin film such as polyethylene terephthalate, polyethylene isophthalate, polyethylene naphthalate and polybutylene terephthalate; a cellulose-based resin film such as diacetylcellulose and triacetylcellulose; a polyolefin-based resin film such as polyethylene, polypropylene, a polylolefin having a cyclo-based or norbornene structure and an ethylene-propylene copolymer, the like, or a combination thereof. In some embodiments, the protective films 210 and 230 may include a cellulose-based resin film such as triacetylcellulose (TAC).

In some embodiments, the protective films 210 and 230 may be attached to the polarizer 220 through an adhesive layer. For example, the adhesive layer may be formed by coating a photocurable adhesive composition on an attachment surface of the polarizer 220 or the protective films 210 and 230 and then crosslinking the adhesive composition by an exposure process. The photocurable adhesive composition may include an acrylate-based photo-polymerizable compound, a photo-polymerization initiator, and a solvent.

The term “adhesive layer” herein is used to encompass a pressure-sensitive adhesive layer or a bonding layer.

The curl-suppression layer 300 may be stacked on the polarizing plate 200. According to embodiments of the disclosure, the curl-suppression layer 300 may include a polymer film stretched in a direction crossing a stretching direction of the polarizer 220.

According to embodiments, the curl-suppression layer 300 may include an ultra-high molecular weight polyethylene (UHMWPE). The UHMWPE may have a weight average molecular weight of 1 million or more, e.g., from about 2 million to about 8 million, or from about 3 million to about 7 million.

The curl-suppression layer 300 may be aligned on the polarizer 220 so that the stretching direction of the curl-suppression layer 300 intersects the stretching direction of the polarizer 220. Therefore, curls generated in an absorption axis direction of the polarizer 220 may be buffered or absorbed.

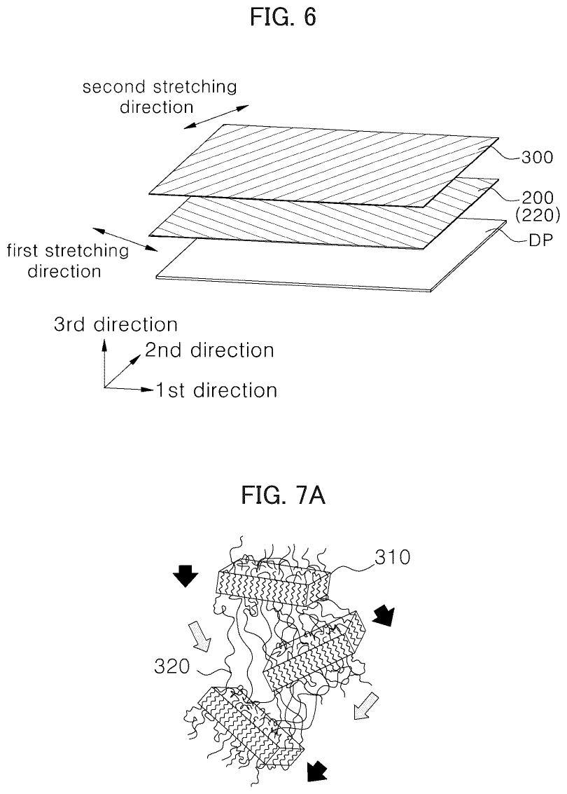

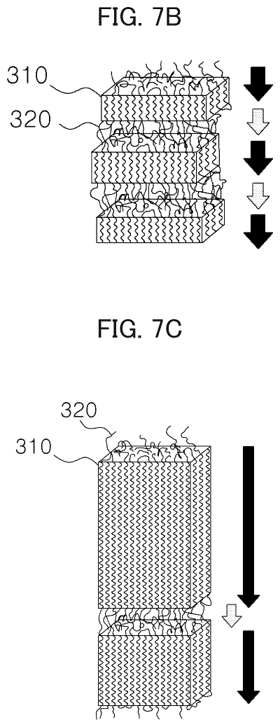

The stretching direction and physical properties of the curl-suppression layer 300 will be described in more detail with reference to FIGS. 6 and 7.

The window structure WS may be stacked on the curl-suppression layer 300.

In some embodiments, the polarizing plate 200 may be attached on the display panel DP or the encapsulation layer TFE by a first adhesive layer 50. The curl-suppression layer 300 may be attached on the polarizing plate 200 by a second adhesive layer 60. The window structure WS may be attached on the curl-suppression layer 300 by a third adhesive layer 70.

The first to third adhesive layers 50, 60 and 70 may include an adhesive material such as an optically clear adhesive (OCA) or an optically clear resin (OCR).

Referring to FIG. 3, the display device may further include a touch sensor layer TS. In some embodiments, the touch sensor layer TS may be included in the form of a module including a touch sensor substrate TSS and a sensing electrode layer TSE formed on a top surface of the touch sensor substrate TSS. In this case, an adhesive layer may be formed between a bottom surface of the touch sensor substrate TSS and the encapsulation layer TFE to attach the touch sensor layer TS in the form of a module on the encapsulation layer TFE.

In some embodiments, the touch sensor substrate TSS may be omitted. The sensing electrode layer TSE may be included in an on-cell type layer deposited (e.g., directly deposited) and patterned on the encapsulation layer TFE.

The polarizing plate 200 may be disposed on the touch sensor layer TS by the first adhesive layer 50 to efficiently suppress or reduce reflection of an external light caused by the sensing electrode layer TSE.

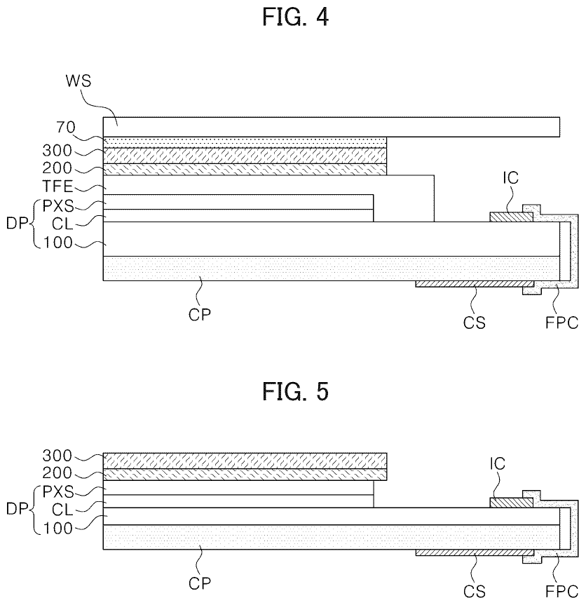

FIGS. 4 and 5 are partially enlarged schematic cross-sectional views illustrating display devices according to embodiments. For example, FIGS. 4 and 5 are partially enlarged schematic cross-sectional views including a bezel area or a peripheral area of the display device.

Referring to FIG. 4, as described above, the encapsulation layer TFE may be formed on the display panel DP including the base substrate 100, the circuit layer CL, and the pixel structure PXS, and the polarizing plate 200 and the curl-suppression layer 300 may be sequentially disposed on the encapsulation layer TFE. The window structure WS may be attached on the curl-suppression layer 300.

An integrated circuit chip IC may be disposed on an end portion of a peripheral area of the base substrate 100. The integrated circuit chip IC may be mounted on (e.g., directly on) the base substrate 100 in a chip-on-glass (COG) form, or may be electrically connected by an additional film on the base substrate 100 in a chip-on-film (COF) form.

An end portion of a circuit board (e.g., a flexible printed circuit board FPC) may be electrically connected to the integrated circuit chip IC through, e.g., an anisotropic conductive film ACF, and may be bent to a bottom surface of the cover panel CP. Accordingly, another end portion of the flexible printed circuit board FPC may be electrically connected to a circuit structure CS disposed under a bottom surface of the cover panel CP. The circuit structure CS may include a driving circuit portion such as a rigid printed circuit board, a driving circuit chip, or the like.

As described above, the display device may be implemented in the form of an electronic device including the circuit board and the driving circuit portion.

Referring to FIG. 5, the display device may be implemented in the form of an ultra-thin (UT) display. According to embodiments, the base substrate 100 may be formed using an ultra-thin substrate such as UTG, and a thickness of the display panel DP may be reduced in a range of about 0.05 mm to about 0.3 mm, or from about 0.1 mm to about 0.25 mm.

In some embodiments, the encapsulation layer TFE may be omitted, and the polarizing plate 200 may be attached on (e.g., directly on) the display panel DP by, e.g., the first adhesive layer 50.

In some embodiments, the window structure WS of FIG. 4 may also be omitted. The curl-suppression layer 300 may be disposed on the polarizing plate 200 and may substantially serve as a window of the display device. For example, the curl-suppression layer 300 may be provided as an outermost layer exposed to an outside of the display device and may provide a viewing surface for a user.

As described above, the curl-suppression layer 300 may have a high elongation and high modulus structure, and may have improved transparency and shock absorption properties. Thus, the curl-suppression layer 300 may effectively suppress a curl caused by the polarizing plate 200, and may be effectively provided as an external protective layer of the display device.

FIG. 6 is a schematic exploded perspective view showing alignment of stretching directions of a curl-suppression layer and a polarizer.

Referring to FIG. 6, the polarizer 220 included in the polarizing plate 200 may be stretched in a first stretching direction. Accordingly, the polarizer 220 may have a stretching axis or an absorption axis in the first stretching direction.

The polarizer 220 may be, e.g., a film in which a dichroic pigment is adsorbed and oriented on a stretched polyvinyl alcohol-based resin film. The polyvinyl alcohol-based resin may be obtained by saponifying a polyvinyl acetate-based resin.

Examples of the polyvinyl acetate-based resin include polyvinyl acetate, which is a homopolymer of vinyl acetate, or a copolymer of vinyl acetate and another monomer copolymerizable therewith. Examples of another monomer copolymerizable with vinyl acetate include an unsaturated carboxylic acid-based monomer, an unsaturated sulfonic acid-based monomer, an olefin-based monomer, a vinyl ether-based monomer, an acrylamide-based monomer having an ammonium group, the like, or a combination thereof.

A degree of saponification of the polyvinyl alcohol-based resin may be in a range from about 85 mol % to about 100 mol %, preferably from about 98 mol % or more.

For example, processes such as a uniaxial stretching of the polyvinyl alcohol-based film, dyeing and adsorption of a dichroic dye, treating with an aqueous boric acid solution, washing with water, and drying may be continuously performed to form the polarizer 220. The polarizer 220 having a first stretching axis or an absorption axis in the first stretching direction may be formed by the uniaxial stretching.

According to embodiments, an acute angle (a first crossing angle) formed by the first stretching direction and the first direction (longitudinal direction of the display device) may be in a range from about 20° to about 70°. In an embodiment, the first crossing angle may be in a range from about 30° to about 60°, or from about 35° to about 55°.

The curl-suppression layer 300 may be a film that is stretched in a second stretching direction to have a second stretching axis. The second stretching direction may be parallel to the top surface of the display device or the display panel DP together with the first stretching direction, and may form a second crossing angle with the first stretching direction.

The second crossing angle refers to an angle of 90° or less among angles formed by the first stretching axis and the second stretching axis, and the second crossing angle may be in a range from about 60° to about 90°. In some embodiments, the second crossing angle may be in a range from about 70° to about 90°, from about 80° to about 90°, or from about 85° to about 90°. In an embodiment, the second crossing angle may be substantially about 90°.

Curl or warpage of the display panel DP may be caused by the first stretching axis of the polarizing plate 200. For example, curl or warpage in which both end portions or both edges of the display panel DP in the first stretching direction rise in a direction toward a display surface (e.g., a visual side) may occur. The curl or warpage may be further intensified in the ultra-thin (UT) display illustrated in FIG. 5.

According to embodiments of the disclosure, the curl-suppression layer 300 having the second stretching axis may be disposed in the display device such that the first stretching axis and the second stretching axis form the second crossing angle. Thus, the curl or warpage caused by the polarizing plate 200 may be buffered or suppressed.

Further, as will be described with reference to FIGS. 7A, 7B, and 7C, the curl-suppression layer 300 may include a UHMWPE film having high modulus properties, and overall curl of the display device may be suppressed by the high modulus properties.

FIGS. 7A, 7B, and 7C are schematic perspective views showing a stretching process of a curl-suppression layer according to embodiments.

Referring to FIG. 7A, a pre-laminate may be formed by extruding a powder or a pellet-type preform of UHMWPE through a pair of rollers.

The pre-laminate may have a shape in which a crystal portion 310 and an amorphous portion 320 are mixed, and a volume or a length of the amorphous portion 320 may be large.

Referring to FIG. 7B, the pre-laminate may be stretched in the second stretching directions (an arrow direction of (b) and (c)) through a heat-stretching process. Accordingly, a length of the amorphous portion 320 may be decreased, a volume and a length of the crystal portion 310 may be increased.

Referring to FIG. 7C, the heat-stretching process may be additionally performed, so that the volume or the length of the crystal portion 310 may be further increased to increase a draw ratio and a modulus.

For example, FIG. 7B illustrates a draw ratio state in a range of about 3 to about 80, and FIG. 7C illustrates a draw ratio state exceeding 100.

A temperature of the heat-stretching process may range from about 120° C to about 160° C. In an embodiment, the temperature of the heat-stretching process may range from about 130° C to about 155° C. In some embodiments, the heat-stretching process may include multiple sequential heat-stretching processes. The heat-stretching processes may be successively performed while sequentially increasing a temperature of each heat-stretching.

For example, the heat-stretching process may include a first heat-stretching performed at a temperature of about 120° C or more and less than about 140° C, a second heat-stretching performed at a temperature of about 140° C or more and less than about 150° C, and a third heat-stretching performed at a temperature of about 150° C or more and less than about 160° C (or less than about 155° C).

Through the sequential performance of the first to third heat-stretching processes, uniformity of physical properties of the UHMWPE film may be improved, and a constant draw ratio may be provided throughout an entire film.

The draw may be a ratio of a film length after the heat-stretching process relative to a film length in the pre-laminated state.

For example, a draw rate of the heat-stretching process may be in a range from about 40 mm/min to about 80 mm/min, from about 45 mm/min to about 70 mm/min, or from about 50 mm/min to about 65 mm/min. In the above range, a uniform draw ratio may be readily achieved.

The draw ratio of the curl-suppression layer 300 or the UHMWPE film may be in a range from about 30 to about 200. In an embodiment, the draw ratio of the curl-suppression layer 300 or the UHMWPE film may be in a range from about 40 to about 150, or from about 50 to about 130.

A tensile modulus of the curl-suppression layer 300 or the UHMWPE film may be in a range from about 70 GPa to about 130 GPa. In an embodiment, the tensile modulus of the curl suppression layer 300 or the UHMWPE film may be in a range from about 70 GPa to about 125 GPa, or from about 75 GPa to about 100 GPa.

The tensile modulus can be measured according to a standard of ASTM D638.

In the draw ratio and the tensile modulus ranges, sufficient curl-suppression may be implemented through the high modulus properties of the curl-suppression layer 300 without degrading overall flexibility of the display device. In the draw ratio range, the curl-suppression layer 300 may have sufficient transparency, and may be directly provided as an external protective film of the display device as illustrated in FIG. 5.

A thickness of the curl-suppression layer 300 may be greater than or equal to a thickness of the polarizer 220 (e.g., a PVA-stretched resin film). In an embodiment, the thickness of the curl-suppression layer 300 may be greater than a thickness of the polarizer 220.

For example, the thickness of the polarizer 220 may be in a range from about 10 μm to about 15 μm. The thickness of the curl-suppression layer 300 may be in a range from about 12 μm to about 400 μm, from about 15 μm to about 300 μm, or from about 20 μm to about 200 μm. In the thickness range, curl caused by the polarizer 220 may also be buffered or reduced while sufficiently suppressing curls from other components of the display device by the curl-suppression layer 300.

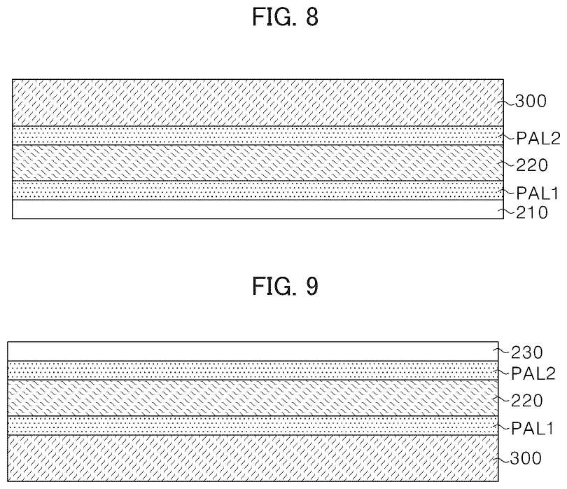

FIGS. 8 to 12 are schematic cross-sectional views illustrating a combination of a polarizing plate and a curl-suppression layer according to embodiments.

Referring to FIGS. 8 and 9, the curl-suppression layer 300 may be included as a protective film of the polarizer 220. Accordingly, the curl-suppression layer 300 may be included in an element or a member that may be substantially integral or unitary with the polarizing plate 200.

As illustrated in FIG. 8, the curl-suppression layer 300 may substantially replace the second protective film 230 of the polarizing plate 200 and may be directly attached to a top surface of the polarizer 220. For example, the curl-suppression layer 300 may be directly attached to the top surface of the polarizer 220 through a second polarizer adhesive layer PAL2.

The first protective film 210 may be attached to a bottom surface of the polarizer 220 through a first polarizer adhesive layer PAL1.

As illustrated in FIG. 9, the curl-suppression layer 300 may substantially replace the first protective film 210 of the polarizing plate 200 and may be directly attached to the bottom surface of the polarizer 220. For example, the curl-suppression layer 300 may be directly attached to the bottom surface of the polarizer 220 through the first polarizer adhesive layer PAL1.

The second protective film 230 may be attached to the top surface of the polarizer 220 through the second polarizer adhesive layer PAL2.

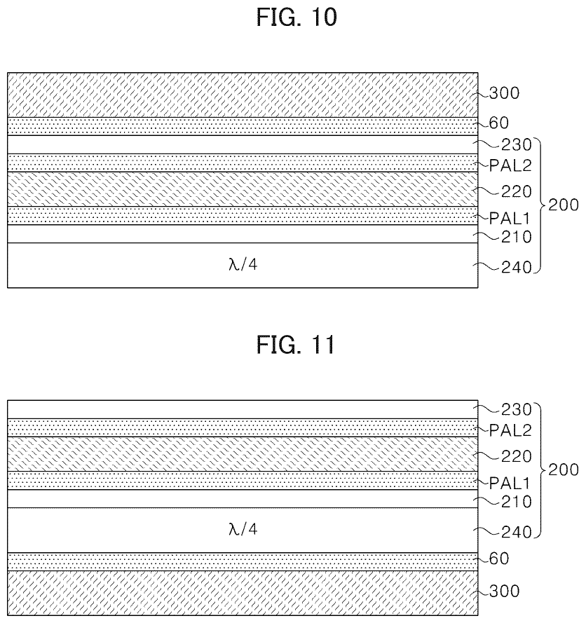

Referring to FIG. 10, the polarizing plate 200 may further include a quarter-wavelength plate 240 (indicated by λ/4). The quarter-wavelength plate 240 may be disposed under the polarizer 220 and may be closer to the display panel DP than the polarizer 220.

An external light passing through the polarizer 220 may be converted into a circularly polarized light by a quarter-wavelength plate 240, and may be reflected again by the display panel DP to be converted into a reversely rotated circularly polarized light. The reflected external light source may pass through the quarter-wavelength plate 240 to be converted into a linearly polarized light and be absorbed by the polarizer 220.

As illustrated in FIG. 10, the quarter-wavelength plate 240, the polarizer 220, and the curl-suppression layer 300 may be sequentially stacked on each other. For example, the curl-suppression layer 300 may be attached onto the second protective film 230 of the polarizing plate 200 through the second adhesive layer 60. The first protective film 210 and the second protective film 230 may be attached to the bottom surface and the top surface of the polarizer 220 through the first polarizer adhesive layer PAL1 and the second polarizer adhesive layer PAL2, respectively.

Referring to FIG. 11, the curl-suppression layer 300 may be disposed below the quarter-wavelength plate 240. For example, the curl-suppression layer 300 may adhere to the bottom surface of the quarter-wavelength plate 240 through the second adhesive layer 60.

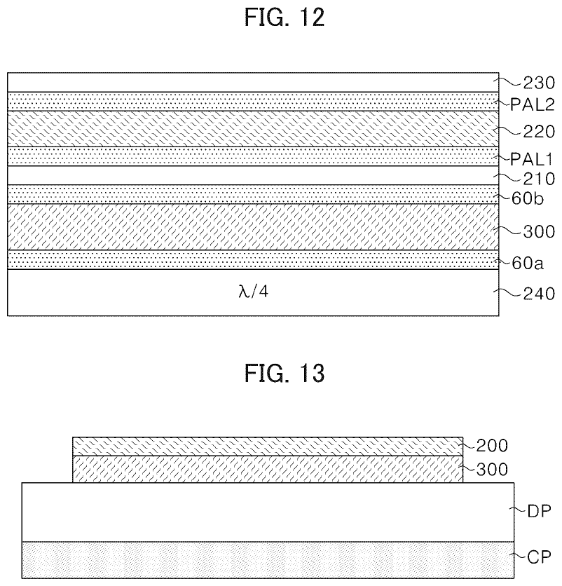

Referring to FIG. 12, the curl-suppression layer 300 may be disposed between the polarizer 220 and the quarter-wavelength plate 240.

For example, a bottom surface of the curl-suppression layer 300 may be attached to the quarter-wavelength plate 240 by a second lower adhesive layer 60a, and a top surface of the curl-suppression layer 300 may be attached to a bottom surface of the first protective film 210 by a second upper adhesive layer 60b.

FIGS. 13 to 15 are schematic cross-sectional views illustrating display devices according to embodiments.

Referring to FIG. 13, the curl-suppression layer 300 may be disposed between the polarizing plate 200 and the display panel DP and may directly block propagation of the curl generated by the polarizing plate 200 to the display panel DP.

In some embodiments, the encapsulation layer TFE may be disposed between the curl-suppression layer 300 and the display panel DP. The curl-suppression layer 300 may be attached onto the display panel DP or the encapsulation layer TFE through the second adhesive layer 60.

The polarizing plate 200 may be attached onto the curl-suppression layer 300 through the first adhesive layer 50. In some embodiments, the window structure WS may be attached onto the polarizing plate 200 through the third adhesive layer 70. In some embodiments, as described with reference to FIG. 5, the window structure WS and the encapsulation layer TFE may be omitted.

In an embodiment, the curl-suppression layer 300 may be disposed between the touch sensor layer TS (see FIG. 3) and the polarizing plate 200. In an embodiment, the curl-suppression layer 300 may be disposed between the touch sensor layer TS and the display panel DP.

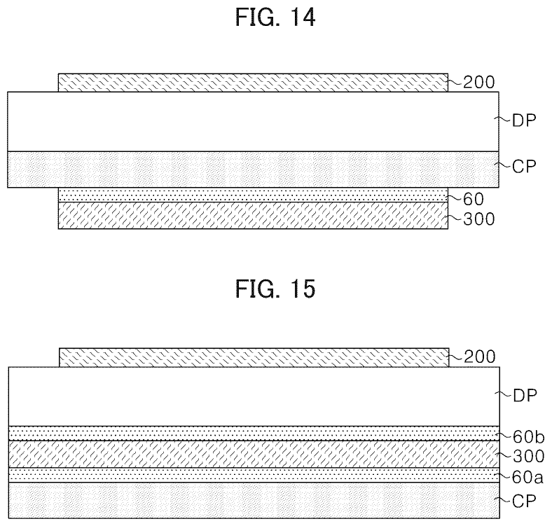

Referring to FIGS. 14 and 15, the curl-suppression layer 300 may be disposed under the display panel DP. Accordingly, the curl-suppression layer 300 may suppress a curl generated in an upward direction by the polarizing plate 200 under the display panel DP. A supporting force of an upper structure including the display panel DP may be provided by the high modulus properties of the curl-suppression layer 300.

As illustrated in FIG. 14, in some embodiments, the curl-suppression layer 300 may be disposed under the cover panel CP. For example, the curl-suppression layer 300 may be attached to a bottom surface of the cover panel CP through the second adhesive layer 60.

As illustrated in FIG. 15, in some embodiments, the curl-suppression layer 300 may be disposed between the display panel DP and the cover panel CP. For example, the curl-suppression layer 300 and the cover panel CP may be attached to each other through the second lower adhesive layer 60a. The curl-suppression layer 300 and the display panel DP may be attached to each other through the second upper adhesive layer 60b.

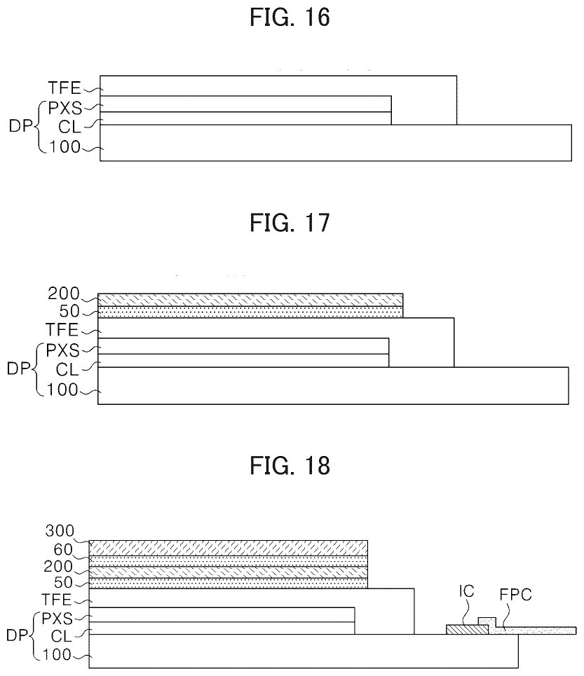

FIGS. 16 to 19 are schematic cross-sectional views illustrating a method of manufacturing a display device according to embodiments.

Referring to FIG. 16, as described with reference to FIG. 2, the circuit layer CL and the pixel structure PXS may be formed on the base substrate 100 to form the display panel DP.

In some embodiments, the encapsulation layer TFE overlapping the circuit layer CL and the pixel structure PXS may be further formed on the base substrate 100. As illustrated in FIG. 5, in the case of the ultra-thin display, the encapsulation layer TFE may be omitted.

Referring to FIG. 17, the polarizing plate 200 may be attached onto the display panel DP or the encapsulation layer TFE using the first adhesive layer 50. As described with reference to FIG. 6, the polarizing plate 200 may include the polarizer 220 having a stretching axis or an absorption axis in the first stretching direction. The polarizing plate 200 may be aligned on the display panel DP such that the first stretching direction of the polarizer 220 may form a first crossing angle with a longitudinal direction of the display device.

Referring to FIG. 18, as described with reference to FIGS. 7A, 7B, and 7C, the curl-suppression layer 300 having the draw ratio and tensile modulus (e.g., the predetermined or selectable draw ratio and tensile modulus) in the second stretching direction may be formed through the heat-stretching of the UHMWPE. For example, the curl-suppression layer 300 may be attached onto the polarizing plate 200 using the second adhesive layer 60.

As described above, the first stretching direction of the polarizer 220 and the second stretching direction of the curl-suppression layer 300 may be aligned to form a second crossing angle.

Thereafter, an integrated circuit chip IC may be combined or mounted in a peripheral or non-pixel area of the base substrate 100, and a flexible printed circuit board FPC and the integrated circuit chip IC may be electrically connected to each other by a heat compression using, e.g., an anisotropic conductive film (ACF).

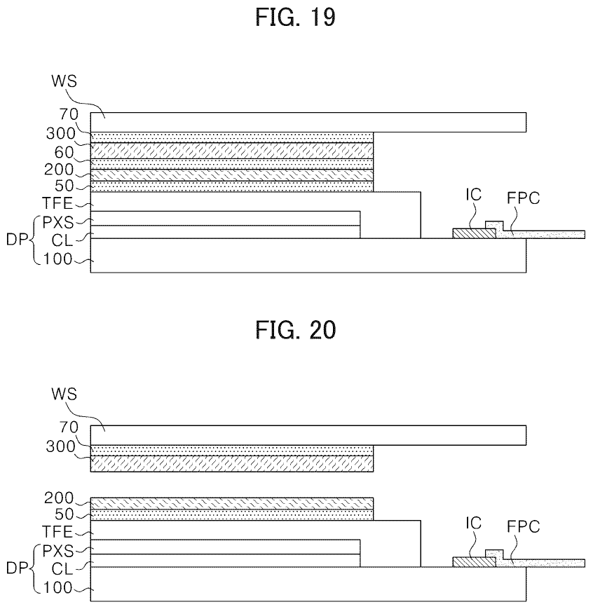

Referring to FIG. 19, the window structure WS may be stacked on the curl-suppression layer 300. For example, the window structure WS may be attached to a top surface of the curl-suppression layer 300 by using the third adhesive layer 70.

In some embodiments, as described with reference to FIG. 5, the window structure WS may be omitted so that the curl-suppression layer 300 may be substantially provided as a window of the display device.

Thereafter, as described with reference to FIGS. 4 and 5, the cover panel CP may be disposed under the display panel DP. Thereafter, the circuit structure CS and the flexible printed circuit board FPC may be connected under the cover panel CP by bending the flexible printed circuit board FPC.

Although FIG. 16 to FIG. 19 illustrate that the curl-suppression layer 300 may be formed on the polarizing plate 200, the location of the curl-suppression layer 300 may be changed as described with reference to FIGS. 8 to 15. For example, the curl-suppression layer 300 may be disposed under the display panel DP together with the cover panel CP.

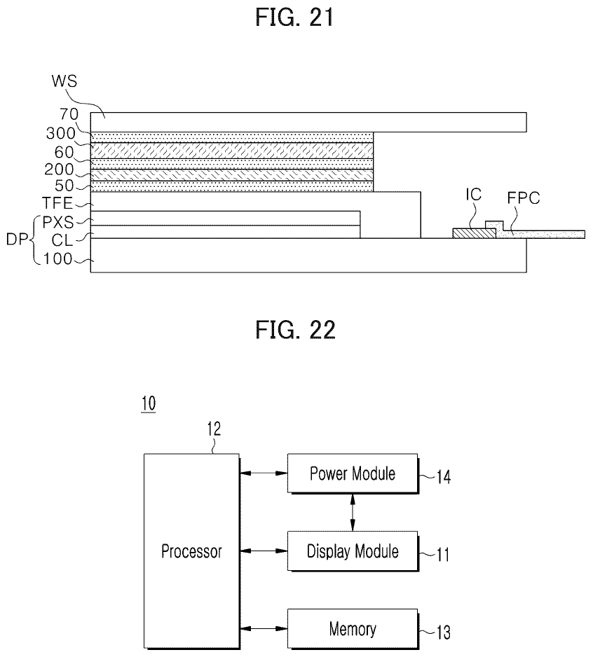

FIGS. 20 and 21 are schematic cross-sectional views illustrating a method of manufacturing a display device according to some embodiments. Detailed descriptions of processes substantially the same as or similar to those described with reference to FIGS. 16 to 19 are omitted.

Referring to FIG. 20, the curl-suppression layer 300 may be attached to the window structure WS through the third adhesive layer 70. Accordingly, the curl-suppression layer 300 and the window structure WS may be prepared in an element or a member that may be substantially integral or unitary with each other before being coupled to the display panel DP.

Referring to FIG. 21, the window structure WS including the curl-suppression layer 300 may be stacked on the polarizing plate 200 using the second adhesive layer 60.

For example, the curl-suppression layer 300 may prevent damage due to impact on the window structure (WS) including a glass substrate and may improve stability in a lamination process of the display panel (DP) and the window structure (WS).

FIG. 22 is a schematic block diagram of an electronic device in accordance with an embodiment.

Referring to FIG. 22, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. In case that the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Some of individual modules functionally included in a module may be included in the display device, and others may be provided separately from the display device. For example, the display module 11 may include the display device, and the processor 12, the memory 13 and the power module 14 may be provided in the form of another device in the electronic device 10 different from the display device.

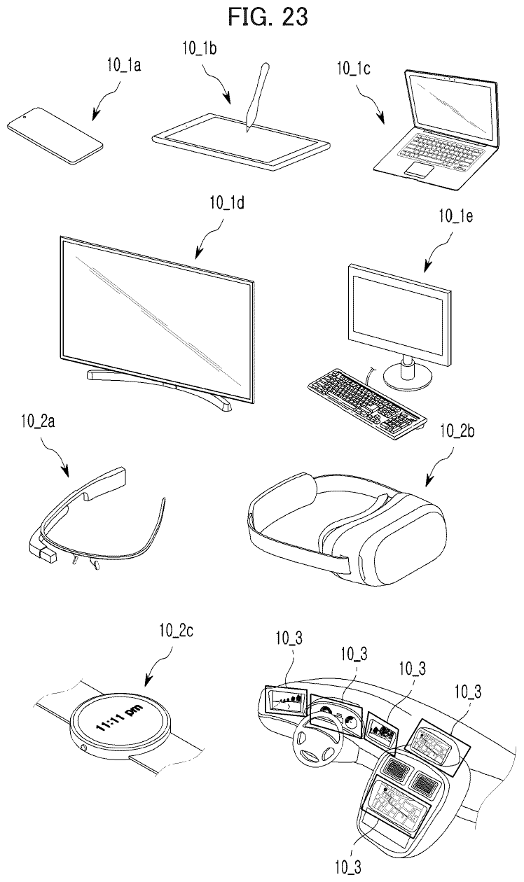

FIG. 23 is a schematic diagram of an electronic device in accordance with various embodiments.

Referring to FIG. 23, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, and the like. The electronic device may include a virtual reality glass or an augmented reality glass.

Although embodiments have been disclosed for illustrative purposes, those skilled in the art will appreciate that various modifications, additions and substitutions are possible, without departing from the scope and spirit of the disclosure as disclosed in the accompanying claims and their equivalents.

What is claimed is:

1. A display device, comprising:
a display panel including a pixel structure;
a polarizing plate disposed on the display panel, the polarizing plate including a polarizer that has a stretching axis in a first stretching direction parallel to an upper surface of the display panel; and
a curl-suppression layer disposed on or under the display panel, the curl-suppression layer being stretched in a second stretching direction crossing the first stretching direction and including an ultra-high molecular weight polyethylene (UHMWPE).

2. The display device of claim 1, wherein a tensile modulus of the curl-suppression layer is in a range from about 70 GPa to about 130 GPa.

3. The display device of claim 1, wherein a thickness of the curl-suppression layer is greater than a thickness of the polarizer.

4. The display device of claim 3, wherein
a thickness of the polarizer is in a range from about 10 μm to about 15 μm, and
a thickness of the curl-suppression layer is in a range from about 12 μm to about 400 μm.

5. The display device of claim 1, wherein
the first stretching direction forms a first crossing angle with a longitudinal direction of the display panel, and
the second stretching direction is parallel to the upper surface of the display panel and forms a second crossing angle with the first stretching direction.

6. The display device of claim 5, wherein the first crossing angle is in a range from about 20° to about 70°.

7. The display device of claim 5, wherein the second crossing angle is in a range from about 60° to about 90°.

8. The display device of claim 1, wherein the polarizing plate and the curl-suppression layer are sequentially stacked on each other from the upper surface of the display panel.

9. The display device of claim 1, wherein the curl-suppression layer is disposed between the display panel and the polarizing plate.

10. The display device of claim 1, wherein the curl-suppression layer serves as an outermost layer of the display device.

11. The display device of claim 1, further comprising:
a cover panel disposed under the display panel, wherein
the cover panel and the display panel are sequentially stacked on each other from the curl-suppression layer.

12. The display device of claim 1, further comprising:
a cover panel under the display panel, wherein
the curl-suppression layer is disposed between the display panel and the cover panel.

13. The display device of claim 1, wherein the curl-suppression layer is directly attached to an upper surface or a lower surface of the polarizer.

14. The display device of claim 13, wherein the polarizing plate further comprises a protective film attached to a surface to which the curl-suppression layer is not attached to the upper surface or the lower surface of the polarizer.

15. The display device of claim 1, further comprising:
a quarter-wavelength plate disposed between the polarizer and the display panel, wherein
the curl-suppression layer is disposed between the quarter-wavelength plate and the polarizer.

16. A display device, comprising:
a display panel including a pixel structure;
a polarizing plate disposed on the display panel, the polarizing plate including a polarizer that has a stretching axis in a first stretching direction parallel to an upper surface of the display panel; and
a curl-suppression layer disposed on or under the display panel, the curl-suppression layer being stretched in a second stretching direction crossing the first stretching direction and having a tensile modulus in a range of about 70 GPa to about 130 GPa.

17. The display device of claim 16, wherein the curl-suppression layer includes an ultra-high molecular weight polyethylene (UHMWPE).

18. An electronic device, comprising:
a display device;
a memory; and
a processor that executes data included in the memory to control an operation of the display device,
wherein the display device comprises:
a display panel including a pixel structure;
a polarizing plate on the display panel, the polarizing plate including a polarizer that has a stretching axis in a first stretching direction parallel to an upper surface of the display panel; and
a curl-suppression layer disposed on or under the display panel, the curl-suppression layer being stretched in a second stretching direction crossing the first stretching direction and including an ultra-high molecular weight polyethylene (UHMWPE).

19. The electronic device of claim 18, wherein a tensile modulus of the curl-suppression layer is in a range from about 70 GPa to about 130 GPa.

20. The electronic device of claim 18, wherein the electronic device includes virtual or augmented reality glasses, a smartphone, a tablet PC, a laptop, a TV, a desk monitor, smart glasses, a head mounted display, a smart watches, or a vehicle display.
